(19) United States
(12) Patent Application Publication
(10) Pub. No.: US 2025/0142941 A1
(43) Pub. Date: May 1, 2025

(54) OXYGEN CONTROL DURING GATE FORMATION FOR IMPROVED CHANNEL MOBILITY

(71) Applicant: Taiwan Semiconductor Manufacturing Company, Ltd., Hsin-Chu (TW)

(72) Inventors: Shang-Rong Li, Hsinchu City (TW); Chih-Wei Lee, New Taipei City (TW)

(21) Appl. No.: 18/498,305

(22) Filed: Oct. 31, 2023

(51) Int. Cl. H01L 21/8238; H01L 27/092; H01L 29/06; H01L 29/423; H01L 29/66; H01L 29/775; H01L 29/786

(52) U.S. Cl. CPC H10D 84/038; H10D 30/014; H10D 30/6735; H10D 62/121; H10D 84/0167; H10D 84/0172; H10D 30/43; H10D 30/6757; H10D 84/85

(57) ABSTRACT

One aspect of the present disclosure pertains to a method of forming a semiconductor device. The method includes forming a high-k gate dielectric layer over a channel region of a substrate; depositing a work function metal layer over the high-k gate dielectric layer; forming a titanium nitride (TiN) cap over the work function metal layer, wherein the TiN cap includes one or more oxygenated regions; depositing a silicon cap layer over the TiN cap; depositing a conductive glue layer over the silicon cap layer; and depositing a gate fill metal layer over the conductive glue layer to form a gate structure.

### BACKGROUND

The integrated circuit (IC) industry has experienced exponential growth. Technological advances in semiconductor manufacturing have produced generations of ICs, where each generation has smaller and more complex circuits than the previous generation. In the course of IC evolution, functional density (i.e., the number of interconnected IC devices per chip area) has generally increased while geometry size (i.e., dimensions and/or sizes of IC features and/or spacings between these IC features) has decreased. Typically, scaling down has been limited only by an ability to lithographically define IC features at the ever-decreasing geometry sizes.

As feature sizes continue to decrease, improved channel mobility (i.e., carrier mobility in a channel) becomes more and more critical in IC devices such as memory or logic devices. For example, memory devices such as SRAM have continued to scale down into smaller technology nodes (e.g., <10 nm). At these dimensions, SRAM mobility and cell-on current may become lower than as desired. As such, the minimum supply voltage Vmin (i.e., minimum operating voltage) is increased and thus the power efficiency drops. Since channel dimensions are limited by the technology nodes, the gate structures, and particularly the gate interface with the channel, is an area of development that may improve channel mobility.

Therefore, although existing methods of forming gate structures have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments. Further, the accompanying figures may implicitly describe features not explicitly described in the detailed description.

FIG. 1 illustrates a cross-sectional view of a gate structure over a channel region, according to an embodiment of the present disclosure.

FIG. 2 illustrates an enlarged cross-sectional view of a portion of the gate structure shown in FIG. 1.

FIG. 3 is a flow chart of a method to form a semiconductor device having a gate structure over a channel region, in portion or in entirety, according to an embodiment of the present disclosure.

FIG. 4 illustrates flowcharts of different methods of forming a titanium nitride cap, according to embodiments of the present disclosure.

FIG. 5A illustrates a titanium nitride cap having an oxygenated region, and FIG. 5B illustrates an oxygen profile of the titanium nitride cap in FIG. 5A.

FIG. 6A illustrates a titanium nitride cap having multiple oxygenated regions, and FIG. 6B illustrates an oxygen profile of the titanium nitride cap in FIG. 6A.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximately,” “substantially,” and the like, the term is intended to encompass numbers that are within a reasonable range including the number described, such as within +/−10% of the number described, or other values as understood by person skilled in the art. For example, the term “about 5 nm” may encompass the dimension range from 4.5 nm to 5.5 nm. And when comparing a dimension or size of a feature to another feature, the phrases “substantially the same,” “essentially the same,” “of similar size,” and the like, can be understood to be within +/−10% between the compared features, or other values as understood by person skilled in the art. Further, disclosed dimensions of the different features can implicitly disclose dimension ratios between the different features.

The present disclosure relates to forming semiconductor devices with improved channel mobility for higher cell-on current and lowered minimum supply voltage Vmin. Specifically, these improvements are achieved through one or more vacuum breaks (or oxygen treatments) during the gate formation process. The vacuum breaks (or oxygen treatments) oxygenate portions of the gate. Oxygen atoms in these oxygenated portions are subsequently diffused into high-k gate dielectric layers of the gate in a post-gate annealing process. Before the post-gate annealing, a silicon cap is formed over the oxygenated portions. The silicon cap prevents further oxygen atoms from diffusing into the high-k gate dielectric layers. In this way, the amount of oxygen to be diffused is controlled only by the oxygenated regions. By controlling the oxygen levels and by further oxidizing the high-k gate dielectric layer through the oxygenated portions, channel mobility is improved for increased device performance.

To illustrate the various aspects of the present disclosure, methods of forming a semiconductor device are discussed below. Embodiments shown in the present disclosure are implemented with Gate-All-Around (GAA) field effect transistors (FETs), but the present disclosure is not limited thereto. GAA FETs refer to transistors having gate stacks (gate electrodes and gate dielectric layers) surrounding transistor channels, such as vertically-stacked gate-all-around horizontal nanowire or nanosheet MOSFET devices. Those of ordinary skill in the art should appreciate that they may readily use the present disclosure as a basis for designing or modifying other structures for carrying out the same purposes and/or achieving the same advantages of the embodiments introduced herein.

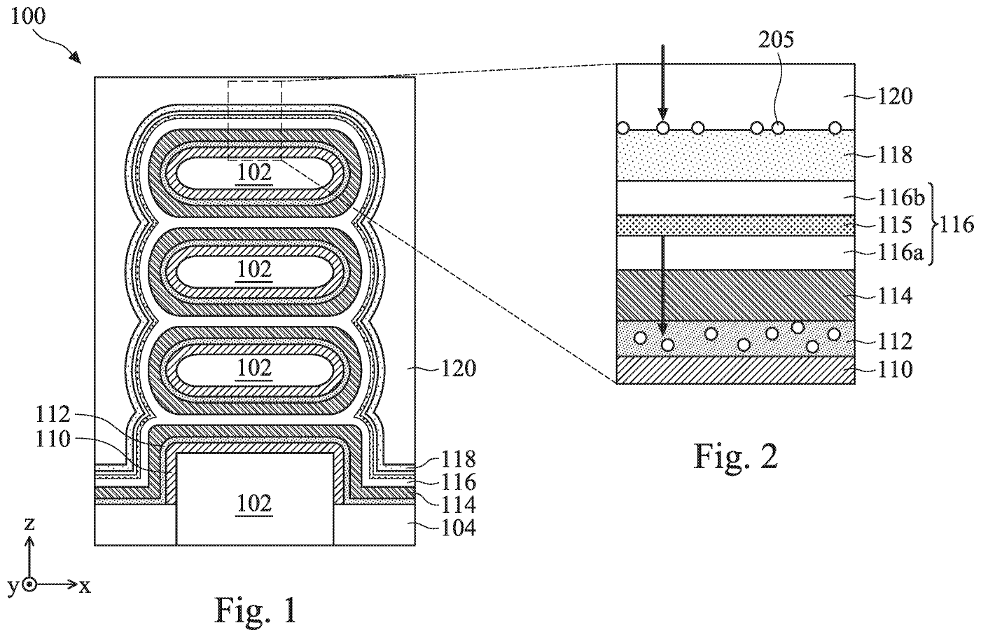

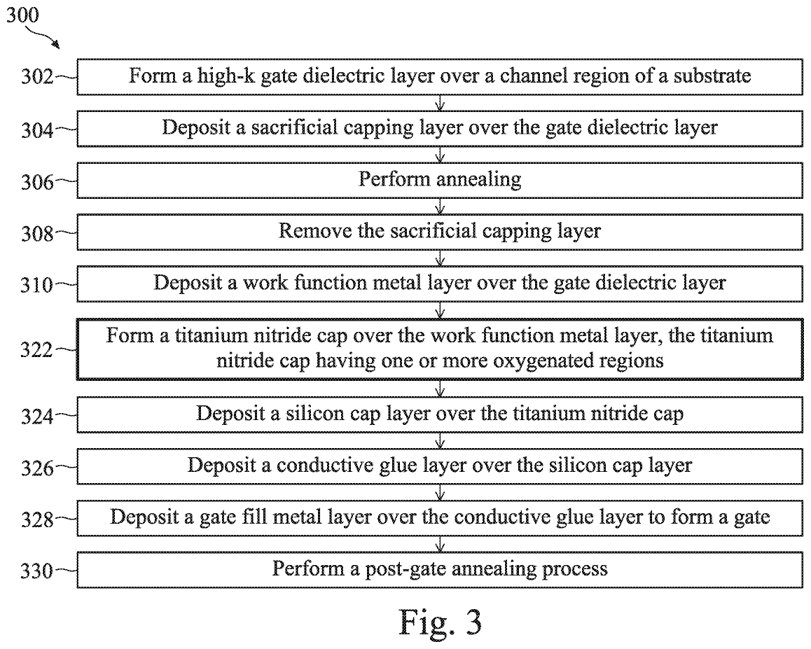

FIG. 1 illustrates a cross-sectional view of a gate structure 100 (or gate stack 100) over a channel region 102, according to an embodiment of the present disclosure. The gate structure 100 extends lengthwise along the x direction and includes several different layers (e.g., interfacial layer 110, gate dielectric layer 112, etc.). These layers will be described in more detail with respect to FIGS. 2 and 3. The channel region 102 is a portion of an active region formed over a substrate (not shown), where the active region extends lengthwise along the y direction (in and out of the page). In the present embodiment, the channel region 102 includes a bottom fin portion and a stack of semiconductor channels over the bottom fin portion. Each of the semiconductor channels are interposed and surrounded by the gate structure 100. The active region, which includes the channel region 102, may be surrounded by and separated from other active regions by an isolation structure 104. The isolation structure 104 covers a top surface of the substrate and surrounds sidewall portions the active region. As shown, the isolation structure 104 surrounds side portions of a bottom fin portion of the channel region 102. The bottom fin portion protrudes from the substrate to above a top surface of the isolation structure 104. The substrate and the active region includes semiconductor materials such as silicon, germanium, silicon carbide, silicon germanium, or other materials. The isolation structure 104 may be a shallow trench isolation (STI) structure having a dielectric material such as silicon oxide, silicon oxynitride, fluorine-doped silicate glass (FSG), a low-k dielectric, combinations thereof, and/or other suitable materials.

Still referring to FIG. 1, although not shown in this view, source/drain features of the active region are disposed adjacent the channel region 102 along the y direction. The source/drain features, the channel region 102, and the gate structure 100 collectively forms a transistor device as part of a semiconductor device. The semiconductor device may be a portion of an integrated circuit (IC) chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other suitable components, or combinations thereof. In some embodiments, the device is included in a non-volatile memory, such as a non-volatile random access memory (NVRAM), a flash memory, an electrically erasable programmable read only memory (EEPROM), an electrically programmable read-only memory (EPROM), other suitable memory type, or combinations thereof. In the present embodiment, the source/drain features, the channel region 102, and the gate structure 100 are transistor portions for a static random access memory (SRAM) device.

FIG. 2 illustrates an enlarged cross-sectional view of a portion of the gate structure 100 shown in FIG. 1. FIG. 2 shows portions of the gate structure 100 formed over a semiconductor channel. Note that the various layers shown in FIG. 2 are not only formed over a semiconductor channel, but they are also formed over the bottom fin portion of the channel region 102 and vertically wrapping around the stack of semiconductor channels (see FIG. 1).

Referring to FIG. 2, the gate structure 100 includes an interfacial layer 110 over a surface of the channel region 102 (e.g., a semiconductor channel), a gate dielectric layer 112 over the interfacial layer 110, a work function metal layer 114 over the gate dielectric layer 112, a titanium nitride (TiN) cap 116 over the work function metal layer 114, a silicon cap layer 118 over the TiN cap 116, and a conductive glue layer 120 over the silicon cap layer 118. Although not shown, a gate fill metal layer may be formed over the conductive glue layer 120 to complete the gate structure 100. In the embodiment shown, the TiN cap 116 includes a first TiN capping layer 116a over the work function metal layer 114, a second TiN capping layer 116b over the first TiN capping layer 116a, and an oxygenated region 115 between the first and second TiN capping layers 116a and 116b. The present disclosure contemplates that oxygen atoms 205 in the oxygenated region 115 will diffuse into the gate dielectric layer 112, and that the silicon cap layer 118 will act as a blocking layer that prevents outside oxygen atoms 205 from diffusing into the TiN cap 116. The gate structure 100 and the oxygen diffusion mechanisms are further described with respect to the method 300 in FIG. 3.

FIG. 3 is a flow chart of a method 300 to form a semiconductor device having a gate structure 100 over a channel region 102, in portion or in entirety, according to an embodiment of the present disclosure. The method 300 in FIG. 3 is described with reference to FIGS. 1 and 2.

At operation 302, the method 300 forms a gate dielectric layer 112 over a channel region 102 of a substrate. The gate dielectric layer 112 is a high-k gate dielectric and includes a high-k dielectric material, such as materials having a dielectric constant greater than silicon oxide (k≈3.9). The gate dielectric layer 112 may include hafnium oxide (HfO₂), zirconium oxide (ZrO₂), lanthanum oxide (La₂O₃), titanium oxide (TiO₂), yttrium oxide (Y₂O₃), strontium titanate (SrTiO₃), aluminum oxide (AlO₂), tantalum oxide (TaO), other suitable metal-oxides, or combinations thereof. The gate dielectric layer 112 may be deposited by any suitable deposition technique such as chemical vapor deposition (CVD) or atomic layer deposition (ALD). As part of or before the operation 302, the method 300 may form an interfacial layer 110 (e.g., silicon oxide layer) over the channel region 102. The gate dielectric layer 112 is then deposited over the interfacial layer 110. The interfacial layer 110 acts as a buffer layer to improve integration between the gate dielectric layer 112 and the semiconductor surface of the channel region 102. The interfacial layer 110 may be formed by chemical oxidation, thermal oxidation, ALD, and/or other suitable methods.

At operation 304, the method 300 deposits a sacrificial capping layer (not shown) over the gate dielectric layer 112 by any suitable deposition technique. The sacrificial capping layer may include a titanium nitride layer and a silicon capping layer over the titanium nitride layer. At operation 306, the method 300 performs an annealing process (also known as post-cap-annealing) to the sacrificial capping layer and the gate dielectric layer 112. The annealing process increases the density, reduce the defects, and improves the quality of the gate dielectric layer 112. The sacrificial capping layer provides padding and protection of the gate dielectric layer 112 during annealing. At operation 308, the method 300 removes the sacrificial capping layer to expose the gate dielectric layer 112. The sacrificial capping layer is removed by any suitable technique, such as wet etching.

At operation 310, after removing the sacrificial capping layer, the method 300 deposits a work function metal layer 114 over the gate dielectric layer 112. The work function metal layer 114 includes a conductive layer having a metal or metal alloy with proper work function such that the corresponding transistor device (e.g., nFET or pFET) is enhanced for its device performance. The work function metal layer 114 may include a metal selected from but not restricted to the group of titanium aluminum nitride (TiAlN), titanium aluminum (TiAl), tungsten aluminide (WAl), titanium nitride (TiN), tantalum nitride (TaN), ruthenium (Ru), molybdenum (Mo), tungsten (W), platinum (Pt), aluminum (Al), or combinations thereof; and may be deposited by CVD, PVD, and/or other suitable process. The work function metal layer 114 is different in composition for a pFET in a first transistor region and an nFET in a second transistor, respectively referred to as an p-type WF metal and a n-type WF metal. Particularly, an n-type WF metal is a metal having a first work function such that the threshold voltage of the associated nFET is reduced. The n-type WF metal is close to the silicon conduction band energy (Ec) or lower work function, presenting easier electron escape. For example, the n-type WF metal has a work function of about 4.2 eV or less. A p-type WF metal is a metal having a second work function such that the threshold voltage of the associated pFET is reduced. The p-type WF metal is close to the silicon valence band energy (Ev) or higher work function, presenting strong electron bonding energy to the nuclei. For example, the p-type work function metal has a WF of about 5.2 eV or higher. In some embodiments, the n-type WF metal includes tantalum (Ta). In other embodiments, the n-type WF metal includes titanium aluminum (TiAl), titanium aluminum nitride (TiAlN), or combinations thereof. In other embodiments, the n-metal include Ta, TiAl, TiAlN, tungsten nitride (WN), or combinations thereof. In some embodiments, the p-type WF metal includes titanium nitride (TiN) or tantalum nitride (TaN). In other embodiments, the p-metal include TiN, TaN, tungsten nitride (WN), titanium aluminum (TiAl), Ru, Pt, or combinations thereof. The n-type WF metal or the p-type WF metal may include various metal-based films as a stack for optimized device performance and processing compatibility.

In some embodiment for illustration, a patterning process is performed to selectively deposit the work function metal layer 114. For example, p-type work function metals are conformally deposited over transistor regions for n-type and p-type devices, then the p-type work function metals are removed in the n-type transistor regions by a lithography and etching process, then the n-type work function metals are deposited.

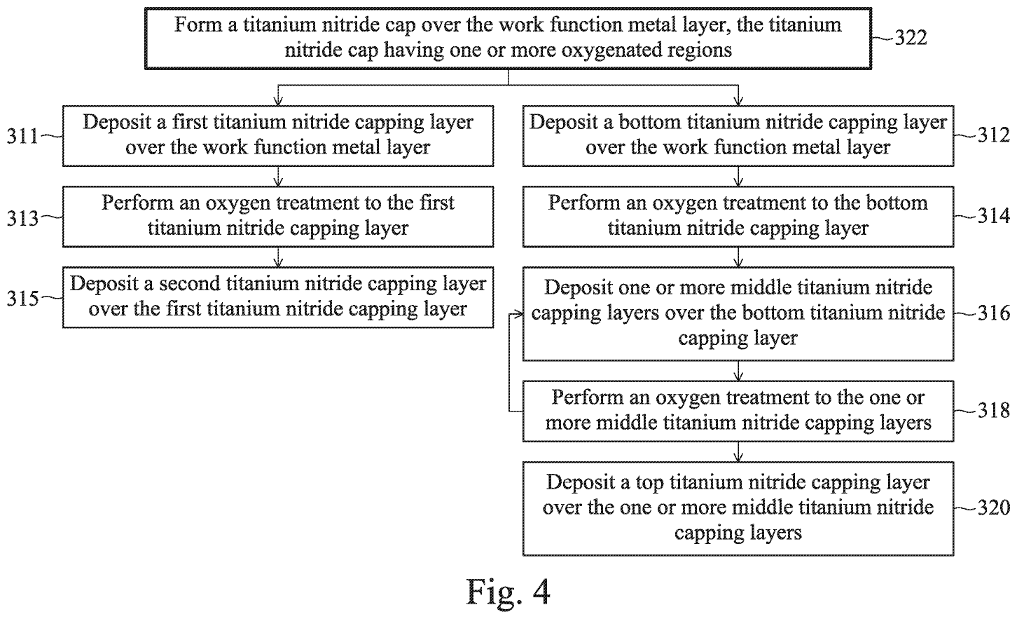

At operation 322, the method 300 forms a TiN cap 116 over the work function metal layer 114. The TiN cap 116 includes one or more oxygenated regions 115. The TIN cap 116 is formed according to the method shown in FIG. 4. FIG. 4 further breaks down operation 322 into various steps.

Referring now to FIG. 4, in a first embodiment, operation 322 includes performing the steps 311, 313, and 315. At step 311, the operation 322 deposits a first TiN capping layer 116a over the work function metal layer 114. In the present embodiment, the first TiN capping layer 116a is deposited through PVD in a PVD chamber. Note that the work function metal layer 114 may be deposited in the same PVD chamber such that the work function metal layer 114 and the first TiN capping layer 116a are deposited in a sequential manner. The PVD chamber is vacuum sealed to reduce contamination from particles and other substances. At step 313, the operation 322 performs an oxygen treatment to the first TiN capping layer 116a. In an embodiment, the oxygen treatment includes removing the workpiece having the first TiN capping layer 116a from the PVD chamber and exposing the first TiN capping layer 116a to an environment outside of the PVD chamber. In an embodiment, the environment is air at room temperature, and the first TiN capping layer 116a is exposed to this environment for at least 3 hours. In another embodiment, the environment is air at a temperature greater than 30° C. and less than 40° C., and the first TiN capping layer 116a is exposed to this environment for less than 2 hours. In any case, the first TiN capping layer is exposed to an environment outside of a vacuum chamber for a period of time, and the vacuum break allows a top surface of the first TiN capping layer 116a to absorb and react with oxygen, thereby forming an oxygenated region 115. The oxygenated region 115 is used for boosting oxygen levels in the gate dielectric layer 112 in a later operation step, thereby enhancing and passivating high-k dielectric vacancies.

To promote and to control the oxygen absorption levels in the oxygenated region 115, the present disclosure contemplates performing a cleaning process to the top surface of the first TiN capping layer 116a before performing the oxygen treatment for enhanced oxygen absorption. The cleaning process may include a wet cleaning process. For example, a wet cleaning process may involve a standard clean solution, such as a solution of ammonia, hydrogen peroxide, and water, or a solution of sulfuric peroxide mixture to clean the top surface of the first TiN capping layer 116a. Further, referring back to step 311, the present disclosure contemplates forming the first TiN capping layer 116a to have a rough top surface. The rough surface may improve oxygen absorption and trapped vacancies during oxygen treatment. The rough surface may be formed by depositing a lower portion of the first TiN capping layer 116a at a first deposition rate, depositing an upper portion of the first TiN capping layer 116a at a second deposition rate, and the second deposition rate is greater than the first deposition rate.

After the oxygen treatment, the operation 322 at step 315 deposits a second TiN capping layer 116b over the first TiN capping layer 116a. At this step, the workpiece is placed back into a vacuum sealed environment such as a PVD chamber. The second TiN capping layer 116b is then deposited over the oxygenated first TiN capping layer 116a. The first TiN capping layer 116a, the oxygenated region 115, and the second TiN capping layer 116b collectively forms a TiN cap 116. In other words, the TiN cap 116 includes an oxygenated region 115 between a top and a bottom region, the oxygenated region having a higher oxygen concentration than the top and the bottom region.

In a second embodiment, the TiN cap 116 may be formed to have multiple oxygenated regions 115. In this case, the operation 322 performs the steps 312, 314, 316, 318, and 320. At step 312, the operation 322 deposits a bottom TiN capping layer (i.e., first TiN capping layer 116a) over the work function metal layer 114. This step is similar to step 311 described above. At step 314, the operation 322 performs an oxygen treatment to the bottom TiN capping layer. This step is similar to step 313 described above. At step 316, the operation 322 deposits one or more middle TiN capping layers 116m (see FIG. 6A) over the bottom TiN capping layer. At step 318, the operation 322 performs an oxygen treatment to the one or more middle TiN capping layers 116m. Note that steps 316 and 318 may be an iterative process depending on how many middle TiN capping layers 116m are formed. In an embodiment, an oxygen treatment is performed for every middle TiN capping layer 116m deposited. At step 320, the operation 322 deposits a top TiN capping layer (i.e., second TiN capping layer 116b) over the one or more middle TiN capping layers 116m to form a TiN cap 116. As such, the formed TiN cap 116 includes multiple oxygenated regions 115 interposed between non-oxygenated regions, where the oxygenated regions have a higher concentration of oxygen than the non-oxygenated regions. Having multiple oxygenated regions 115 may improve oxygen control when diffusing oxygen atoms into the gate dielectric layer 112 in a later processing step. The multiple oxygenated regions 115 may also be tuned to have different oxygen concentration levels.

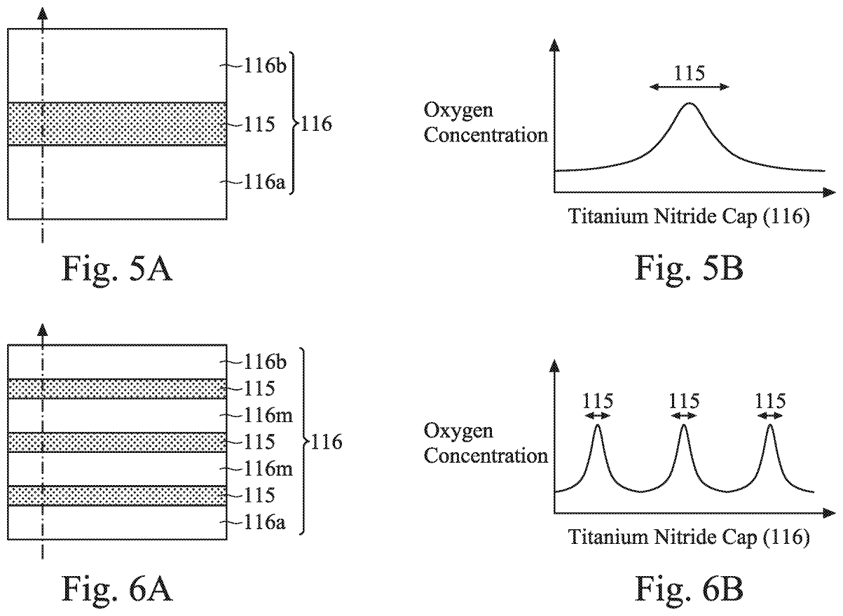

FIG. 5A illustrates a TiN cap 116 having an oxygenated region 115, and FIG. 5B illustrates an oxygen profile of the TiN cap 116 in FIG. 5A. As shown in FIG. 5B, the oxygen concentration in the oxygenated region 115 is greater than the oxygen concentration in the non-oxygenated regions. Changes in oxygen concentration may be gradual across different regions of the TiN cap 116. Note that in the non-oxygenated regions, there may still be a non-zero oxygen concentration. In any case, the middle region of the TiN cap 116 has a greater oxygen concentration than the bottom and top regions.

FIG. 6A illustrate a TiN cap 116 having multiple oxygenated regions 115, and FIG. 6B illustrates an oxygen profile of the TiN cap 116 in FIG. 6A. As shown in FIG. 6B, the oxygen concentration in the oxygenated regions 115 is greater than the oxygen concentration in the non-oxygenated regions. Changes in oxygen concentration may be gradual across different regions of the TiN cap 116. Note that in the non-oxygenated regions, there may still be a non-zero oxygen concentration. As shown, there may be multiple peaks of oxygen concentration corresponding to different oxygenated regions 115 between the bottom and top regions of the TiN cap 116. FIG. 6B shows even oxygen concentrations for each oxygenated region 115. However, in some embodiments, the oxygen concentration may not be even. For example, top oxygenated regions 115 may have a higher oxygen concentration than that of the bottom oxygenated regions 115. One way to vary oxygen concentrations across the different oxygenated regions 115 is by varying the oxygen treatment parameters for the middle TiN capping layers 116m (i.e., varying vacuum break time, temperature, etc.).

Now referring back FIG. 3, after forming the TiN cap 116, the method 300 at operation 324 deposits a silicon cap layer 118 (see FIG. 2) over the TiN cap 116. The silicon cap layer 118 may be deposited by a suitable technique such as CVD or PVD. The silicon cap layer 118 functions as a protection layer to prevent further oxidation into the TiN cap 116 in later processes. At operation 326, the method 300 deposits a conductive glue layer 120 (see FIG. 2) over the silicon cap layer 118 by a suitable technique such as PVD or CVD. The conductive glue layer 120 may include titanium nitride and functions as a seed layer for better surface contact with a subsequent metal fill. At operation 328, the method 300 deposits a gate fill metal layer (not shown) over the conductive glue layer 120 to complete the gate structure 100. The gate fill metal layer may be deposited using CVD, PVD, or other suitable processes. The gate fill metal layer may include a metal such as aluminum (Al), tungsten (W), cobalt (Co), copper (Cu), and/or other suitable materials.

Referring to FIG. 3, the method 300 at operation 330 performs a post-gate annealing process to the workpiece. The post-gate annealing process refers to any annealing step that may be performed after forming the gate structure 100. As shown by the arrows in FIG. 2, the post-gate annealing process drives oxygen atoms 205 in the TiN cap 116 into the gate dielectric layer 112, while the silicon cap layer 118 prevents oxygen atoms 205 from diffusing into the TiN cap 116. In this way, oxygen levels are controlled by varying oxygen concentrations in the oxygenated regions 115, while oxygen not part of the oxygenated regions 115 are filtered out. Note that the silicon cap layer 118 not only prevents extraneous oxygen diffusion during the post-annealing process, but also after the annealing process, such as in subsequent processes and during field operations of the final device. In an embodiment, the post-gate annealing process is a thermal annealing treatment to the gate electrode. In furtherance of the embodiment, the annealing temperatures ranges between 800° C. and 1000° C. In another embodiment, the post-gate annealing process is a dedicated thermal treatment for driving in the oxygen atoms 205. In yet another embodiment, the post-gate annealing process may be a thermal treatment for other portions of the semiconductor device, and the oxygen atoms 205 are driven in as a secondary effect.

During initial formation of the gate dielectric layer 112, the high-k material in the gate dielectric layer 112 may not be sufficiently saturated with oxygen due to process window concerns. By using the oxygenated regions 115 to drive in oxygen atoms 205 into the gate dielectric layer 112, the gate dielectric layer 112 is tuned for better performance. However, the gate dielectric layer 112 is a sensitive layer that require precise tuning. Driving in too much oxygen atoms 205 may over-oxidize the gate dielectric layer 112 and causing defect. As such, the silicon cap layer 118 prevents any extraneous oxygen atoms 205 from reaching into the gate dielectric layer 112. In this way, the precise amount of oxygen diffusion may be controlled by the oxygenated regions 115 without regard to oxygen atoms 205 beyond the silicon cap layer 118.

Although not limiting, the present disclosure offers advantages when forming semiconductor gate structures. One example advantage is controlling oxygen levels between two TiN capping layers. The oxygen levels is tuned through oxygen treatments that may include vacuum breaks when forming the TiN cap. The oxygen treatments creates oxygenated regions that are later used for driving in oxygen atoms into the gate dielectric layer. It has been discovered that driving in these oxygen atoms improves mobility gain by more than 15%, which may result in higher cell-on current by 8% and lowered minimum supply voltage Vmin by 20 to 30 mV. Another example advantage is using a silicon cap layer to block off extraneous oxygen atoms from diffusing into the gate dielectric layer. Another example advantage is driving in oxygen atoms as a secondary effect when performing a post-gate annealing step for a different portion of the semiconductor device.

One aspect of the present disclosure pertains to a method of forming a semiconductor device. The method includes forming a high-k gate dielectric layer over a channel region of a substrate; depositing a work function metal layer over the high-k gate dielectric layer; forming a titanium nitride (TiN) cap over the work function metal layer, wherein the TiN cap includes one or more oxygenated regions; depositing a silicon cap layer over the TiN cap; depositing a conductive glue layer over the silicon cap layer; and depositing a gate fill metal layer over the conductive glue layer to form a gate structure.

In an embodiment, the method further includes performing an annealing process to the gate structure such that oxygen atoms in the TiN cap diffuses into the high-k gate dielectric layer. In a further embodiment, during and after the performing of the annealing process, the silicon cap layer functions to prevent oxygen atoms from diffusing into the TiN cap.

In an embodiment, the forming of the TiN cap includes depositing a first TIN capping layer over the work function metal layer; performing an oxygen treatment to the first TiN capping layer; and depositing a second TiN capping layer over the first TiN capping layer.

In a further embodiment, the first TiN capping layer is deposited in a vacuum sealed physical vapor deposition (PVD) chamber, wherein the oxygen treatment includes removing a workpiece having the first TiN capping layer from the PVD chamber; and exposing the first TiN capping layer to an environment outside of the PVD chamber.

In a further embodiment, the environment is air at room temperature, and the first TiN capping layer is exposed to the environment for at least 3 hours. In another embodiment, the environment is air at a temperature greater than 30° C., and the first TiN capping layer is exposed to the environment for less than 2 hours.

In a further embodiment, after the exposing, the workpiece is placed back into the PVD chamber, and the second TiN capping layer is deposited over the first TiN capping layer in the PVD chamber.

In a further embodiment, the first TiN capping layer is deposited such that a top surface of the first TiN capping layer has a rough surface. In a further embodiment, the rough surface is formed by depositing a lower portion of the first TiN capping layer at a first deposition rate, depositing an upper portion of the first TiN capping layer at a second deposition rate, and the second deposition rate is greater than the first deposition rate.

Another aspect of the present disclosure pertains to a method of forming a semiconductor device. The method includes forming a high-k gate dielectric layer over a channel region of a substrate; depositing a work function metal layer over the high-k gate dielectric layer; depositing a first titanium nitride (TiN) capping layer over the work function metal layer; performing an oxygen treatment to the first TiN capping layer; depositing a second TiN capping layer over the first TiN capping layer to form a TiN cap; depositing a silicon cap layer over the TiN cap; depositing a conductive glue layer over the silicon cap layer; and depositing a gate fill metal layer over the conductive glue layer to form a gate structure.

In an embodiment, before the depositing the work function metal layer, the method further includes depositing a sacrificial capping layer over the high-k gate dielectric layer; performing a first annealing process to the sacrificial capping layer and the high-k gate dielectric layer; and removing the sacrificial capping layer. After the depositing of the gate fill metal layer, the method further includes performing a second annealing process to the gate structure such that oxygen atoms in the TiN cap diffuses into the high-k gate dielectric layer. In a further embodiment, before the depositing of the second TiN capping layer, the method further includes depositing a middle TiN capping layer over the first TiN capping layer; and performing an oxygen treatment to the middle TiN capping layer. The second TiN capping layer is deposited over the middle TiN capping layer.

In an embodiment, the TiN cap has an oxygenated region between a top and a bottom region, the oxygenated region having a higher oxygen concentration than the top and the bottom region. In an embodiment, the performing of the oxygen treatment includes exposing the first TiN capping layer to an environment outside of a vacuum chamber. In an embodiment, before the performing of the oxygen treatment, the method further includes performing a cleaning process to a top surface of the first TiN capping layer.

Another aspect of the present disclosure pertains to a method of forming a semiconductor device. The method includes forming a high-k gate dielectric layer over a channel region of a substrate; depositing a work function metal layer over the high-k gate dielectric layer; depositing a bottom titanium nitride (TiN) capping layer over the work function metal layer; performing an oxygen treatment to the bottom TiN capping layer; depositing one or more middle TiN capping layers over the bottom TiN layer; performing an oxygen treatment to the one or more middle TiN capping layers; depositing a top TiN capping layer over the one or more middle TiN capping layers to form a TiN cap; depositing a silicon cap layer over the TiN cap; depositing a conductive glue layer over the silicon cap layer; and depositing a gate fill metal layer over the conductive glue layer to form a gate structure.

In an embodiment, an oxygen treatment is performed for every middle TiN capping layer deposited. In an embodiment, the TiN cap includes multiple oxygenated regions interposed between non-oxygenated regions, wherein the oxygenated regions have a higher concentration of oxygen than the non-oxygenated regions.

In an embodiment, the method further includes performing an annealing process to the gate structure such that oxygen atoms in the TiN cap diffuses into the high-k gate dielectric layer.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method of forming a semiconductor device, comprising:
forming a high-k gate dielectric layer over a channel region of a substrate;
depositing a work function metal layer over the high-k gate dielectric layer;
forming a titanium nitride (TiN) cap over the work function metal layer, wherein the TiN cap includes one or more oxygenated regions;
depositing a silicon cap layer over the TiN cap;
depositing a conductive glue layer over the silicon cap layer; and
depositing a gate fill metal layer over the conductive glue layer to form a gate structure.

2. The method of claim 1, further comprising:
performing an annealing process to the gate structure such that oxygen atoms in the TiN cap diffuses into the high-k gate dielectric layer.

3. The method of claim 2, wherein during and after the performing of the annealing process, the silicon cap layer functions to prevent oxygen atoms from diffusing into the TiN cap.

4. The method of claim 1, wherein the forming of the TiN cap includes:
depositing a first TiN capping layer over the work function metal layer;
performing an oxygen treatment to the first TiN capping layer; and
depositing a second TiN capping layer over the first TiN capping layer.

5. The method of claim 4, wherein the first TiN capping layer is deposited in a vacuum sealed physical vapor deposition (PVD) chamber, wherein the oxygen treatment includes:
removing a workpiece having the first TiN capping layer from the PVD chamber; and
exposing the first TiN capping layer to an environment outside of the PVD chamber.

6. The method of claim 5, wherein the environment is air at room temperature, and the first TiN capping layer is exposed to the environment for at least 3 hours.

7. The method of claim 5, wherein the environment is air at a temperature greater than 30° C., and the first TiN capping layer is exposed to the environment for less than 2 hours.

8. The method of claim 5, wherein after the exposing, the workpiece is placed back into the PVD chamber, and the second TiN capping layer is deposited over the first TiN capping layer in the PVD chamber.

9. The method of claim 4, wherein the first TiN capping layer is deposited such that a top surface of the first TiN capping layer has a rough surface.

10. The method of claim 9, wherein the rough surface is formed by depositing a lower portion of the first TiN capping layer at a first deposition rate, depositing an upper portion of the first TiN capping layer at a second deposition rate, and the second deposition rate is greater than the first deposition rate.

11. A method of forming a semiconductor device, comprising:
forming a high-k gate dielectric layer over a channel region of a substrate;
depositing a work function metal layer over the high-k gate dielectric layer;
depositing a first titanium nitride (TiN) capping layer over the work function metal layer;
performing an oxygen treatment to the first TiN capping layer;
depositing a second TiN capping layer over the first TiN capping layer to form a TiN cap;
depositing a silicon cap layer over the TiN cap;
depositing a conductive glue layer over the silicon cap layer; and
depositing a gate fill metal layer over the conductive glue layer to form a gate structure.

12. The method of claim 11,
wherein before the depositing the work function metal layer, further comprising:
depositing a sacrificial capping layer over the high-k gate dielectric layer;
performing a first annealing process to the sacrificial capping layer and the high-k gate dielectric layer; and
removing the sacrificial capping layer,
wherein after the depositing of the gate fill metal layer, further comprising:
performing a second annealing process to the gate structure such that oxygen atoms in the TiN cap diffuses into the high-k gate dielectric layer.

13. The method of claim 12, before the depositing of the second TiN capping layer, further comprising:
depositing a middle TiN capping layer over the first TiN capping layer; and
performing an oxygen treatment to the middle TiN capping layer,
wherein the second TiN capping layer is deposited over the middle TiN capping layer.

14. The method of claim 11, wherein the TiN cap has an oxygenated region between a top and a bottom region, the oxygenated region having a higher oxygen concentration than the top and the bottom region.

15. The method of claim 11, the performing of the oxygen treatment includes exposing the first TiN capping layer to an environment outside of a vacuum chamber.

16. The method of claim 11, wherein before the performing of the oxygen treatment, performing a cleaning process to a top surface of the first TiN capping layer.

17. A method of forming a semiconductor device, comprising:
forming a high-k gate dielectric layer over a channel region of a substrate;
depositing a work function metal layer over the high-k gate dielectric layer;
depositing a bottom titanium nitride (TiN) capping layer over the work function metal layer;
performing an oxygen treatment to the bottom TiN capping layer;
depositing one or more middle TiN capping layers over the bottom TiN layer;
performing an oxygen treatment to the one or more middle TiN capping layers;
depositing a top TiN capping layer over the one or more middle TiN capping layers to form a TiN cap;
depositing a silicon cap layer over the TiN cap;
depositing a conductive glue layer over the silicon cap layer; and
depositing a gate fill metal layer over the conductive glue layer to form a gate structure.

18. The method of claim 17, wherein an oxygen treatment is performed for every middle TiN capping layer deposited.

19. The method of claim 17, wherein the TiN cap includes multiple oxygenated regions interposed between non-oxygenated regions, wherein the oxygenated regions have a higher concentration of oxygen than the non-oxygenated regions.

20. The method of claim 17, further comprising:
performing an annealing process to the gate structure such that oxygen atoms in the TIN cap diffuses into the high-k gate dielectric layer.
